(19) United States
(12) Patent Application Publication
(10) Pub. No.: US 2002/0190267 A1
(43) Pub. Date: Dec. 19, 2002

(54) Electrostatically actuated microswitch

(76) Inventor: Janet K. Robertson, Easton, PA (US)

Correspondence Address: HARNESS, DICKEY & PIERCE, P.L.C., P.O. BOX 828, BLOOMFIELD HILLS, MI, 48303, US

(21) Appl. No.: 09/876,409

(22) Filed: Jun. 7, 2001

(51) Int. Cl. H01L 31/111

(52) U.S. Cl. 257/130

(57) ABSTRACT

The present invention is directed to a micro electromechanical system (MEMS) relay having a movable actuator member part that moves laterally in a wafer surface recess into contact with a power terminal. In a preferred embodiment, the movable actuator member is a planar single body comprised of two flat intersecting flexible “S” shaped portions when seen in plan view. A power terminal makes contact with the middle part of one “S”, where it intersects with the other “S”. A pair of electrostatic electrodes are located at each end of the one “S”, to respectively move the middle part of that “S” into and away from contact with a power terminal in the recess. The other “S” serves as a flexible connection to the middle part of the other “S”. Means are provided to electrically isolate the ends of the first “S from its middle part.

### FIELD OF THE INVENTION

This invention relates to an improved micro electromechanical systems (MEMS) relay. It more specifically relates to an electromechanical switch that can be readily made by ordinary semiconductor manufacturing techniques, and can form an integral part of a semiconductor integrated circuit. In other words, this invention also relates to an integrated circuit having an integral electromechanical switch that is made using semiconductor manufacturing technology.

### BACKGROUND OF THE INVENTION

Micro electromechanical systems (MEMS) relays have been made in the past. They are manufactured using semiconductor type manufacturing processes and can be designed to open and close fast and handle relatively high power. On the other hand, prior designs have had drawbacks, including electrical leakage, cost, design flexibility for specific applications, durability, and ease of integration into a conventionally produced integrated circuit. Many designs did not offer ready re-design to accommodate specific electrical loads that were being switched. Some designs allowed switch terminals to be exposed to the ambient, which is ordinarily detrimental to operating life.

More recent MEMS relays attempt to overcome some of these problems by utilizing cantilever beams or one or more diaphragms on the upper and/or lower surfaces of a semiconductor wafer in which they are formed. The MEMS semiconductor wafer is most likely not a semiconductor integrated circuit chip. In such an instance, the MEMS relay and the integrated circuit chip are two separate components that have to be mounted and electrically connected. In membrane and cantilever type MEMS relays, the mechanically movable part of the relay moves perpendicularly to the wafer plane. This can put stress on the bond between the wafer surface and the membrane. Such stress can be detrimental to the life of the relay. This invention avoids the need for such membranes, and thus avoids the drawbacks of incorporating such membranes on a semiconductor wafer. The MEMS relay of this invention, as stated above, needs no surface membranes. It can be made as a separate component in a semiconductor integrated circuit chip, using rather conventional semiconductor processing technology.

In this invention, the movable part of the MEMS relay is a flat actuator member that is disposed in a wafer recess. When it moves, it substantially retains its flatness and moves parallel to the wafer surface into abutment with recessed wall parts. I refer to this movement as horizontal motion. In this horizontal motion, the abutting action does not put tensile stress on the bond of any membranes to the wafer surface. This inherently should improve the life of the MEMS relay, and make it more practical to include it in an integrated circuit chip, which normally has long life. Still further, it may be economically practical to incorporate my MEMS relay into an integrated circuit because it can be designed to utilize some of the same process steps that are used to make an integrated circuit.

### SUMMARY OF THE INVENTION

The present invention is directed to a micro electromechanical system (MEMS) relay having a movable actuator member part that moves laterally in a wafer surface recess into contact with a power terminal. More specifically, an upper surface of a semiconductor wafer has a recess. The movable actuator member is a flexible member disposed in the recess and supported at the edges of the recess. In a preferred embodiment, the movable actuator member is a planar single body comprised of two flat intersecting flexible “S” shaped portions when seen in plan view. In plan view, the middle part of a first “S” shaped portion is integrally joined to one end of a second “S” shaped portion. Both ends of the first “S” and the other end of the second “S” are supported at the edges of the recess. The supported other end of the second “S” is connected to a first power terminal. A second power terminal is located in the recess next to the middle of the first “S”, near its edge opposite to the where it intersects with the one end of the second “S”.

A pair of electrostatic electrodes are located at each end of the first “S”. One electrode of each pair is directly connected to its respective end of the first “S”. The other electrode of each pair is closely spaced and insulated from that end of the first “S”. Application of an electrostatic potential between the pair of electrostatic electrodes at that end of the first “S” attracts that end of the first “S” to its closely spaced insulated electrode. When that end is pulled to the insulated electrode, the middle of the first “S” moves orthogonally into contact with the second power terminal. This closes the microswitch. Conversely, application of an electrostatic potential between the pair of electrostatic electrodes at the other end of the first “S” attracts that end of the second “S” towards its respective closely spaced and insulated electrode. This moves the middle of the first “S” away from the second power terminal, which opens the microswitch. As indicated above, the second “S” is flexible too. It respectively expands and contracts like a spring when the first “S” moves towards and away from the second power terminal.

The middle of the first “S” and the entirety of the second “S” are doped similarly, as for example to p-type conductivity. This provides a low electrical resistance path from the first power terminal to the second power terminal when the microswitch closes. The ends of the first “S” are oppositely doped (i.e., doped to n-type conductivity), to electrically isolate them from the conductive path between the first and second power terminals. A metal layer on the surface of the second “S” can lower the electrical resistance of the path between the first and second power terminals even more.

Other objects, features and advantages of this invention will become more apparent from the following detailed description taken together with the accompanying drawing and claims.

### BRIEF DESCRIPTION OF THE DRAWING

FIG. 1 shows a plan view of the surface of a semiconductor wafer during an intermediate step in the process of making a MEMS relay in accordance with this invention.

FIG. 2 shows a plan view of the surface of a semiconductor wafer at the completion of the process of making a MEMS relay in accordance with this invention. The MEMS relay is shown as formed, in which the intersecting integrated “S” shapes of the movable flexible actuator are in their “as-formed” position.

FIGS. 3A-3J are cross sectional views along the line 3-3 of FIG. 2, respectively showing wafer 10 during process steps A through J.

### DETAILED DESCRIPTION

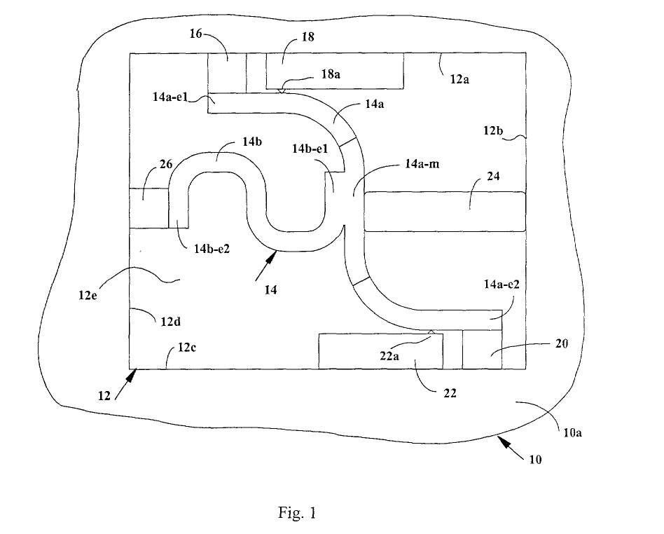

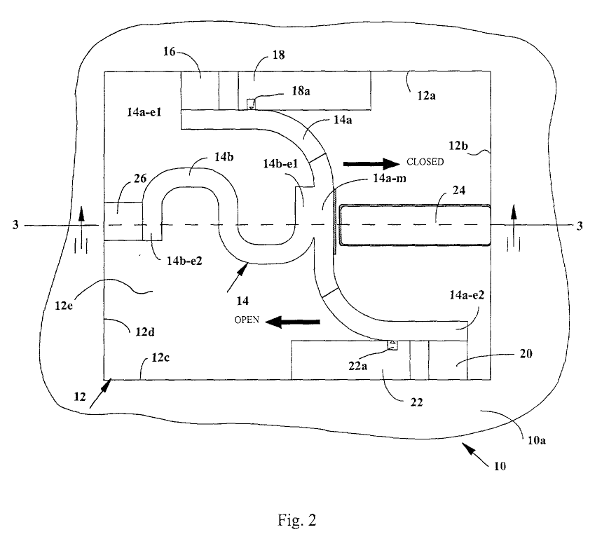

The switch of this invention utilizes electrostatic actuation for rapid switching, such as at about 100 KHz. I also refer to this microswitch as a zero leakage micro electromechanical system (MEMS) relay. The microswitch of this invention employs a flexible actuator member that is laterally, i.e. horizontally, movable in a recess on the surface of an essentially intrinsic (111) monocrystalline silicon wafer. By intrinsic I mean that the silicon wafer has a carrier concentration of no greater than about 1.5×10¹⁰ cm⁻³. However, in some applications, I recognize that one might want to use a starting wafer that is doped lightly p-type or n-type, as for example of the order of 1×10¹⁵ cm⁻³. All of these could be acceptable. When viewed in plan view, as shown in FIGS. 1-2, the preferred flexible actuator member comprises two flexible integrated orthogonal “S” shaped portions. One “S” portion carries electrical current to the middle part of the other “S” portion. The other “S” portion is electrostatically actuated, so as to move its middle portion into contact with an adjacent power terminal.

The “S” shape in the latter portion of the actuator is particularly advantageous because the electrostatic force of attraction will operate over a small distance. Therefore, only relatively small voltages are needed to close and open the microswitch. This “S” shape is not to be confused with the flap actuator of some microvalves. In the microvalves, the “S” is in the cross section of the flap, and moves laterally along the flap. This is a different shape and motion than my actuator, as will hereinafter be understood.

Referring now to FIGS. 1-2, the microswitch of this invention includes a base wafer 10 having a recess 12 formed by recess side walls 12a, 12b, 12c and 12d and bottom wall 12e. Recess 12 contains a flexible actuator 14 etched from the material of wafer 10. FIG. 1 shows the microswitch in an intermediate step of its fabrication, where recess 12 and switch parts are defined in the recess. However, in FIG. 1, as hereinafter explained more fully, recess 12 is not at its final depth and flexible actuator 14 has not yet been released from recess bottom wall 12e. In FIG. 2, recess 12 is at its final depth and the wafer material under flexible actuator 14 has been completely undercut by lateral etching, to release movable actuator 14 from recess bottom wall 12e. As can be seen in FIGS. 1-2, the flexible actuator 14 in my MEMS relay is a unitary body formed by two intersecting flexible “S” shaped portions 14a and 14b. The “S” shaped portions 14a and 14b are formed by etching the surface of wafer 10, to define two integral “S” shaped portions that orthogonally intersect. Hence, the moveable actuator 14 of my MEMS relay is integral with the surface of wafer 10. After the detailed description of this preferred embodiment, an alternative embodiment will be described in which moveable actuator 14 is defined in a coating on the surface of wafer 10.

In this invention, two “S” shaped portions 14a and 14b are integrally connected at substantially a right angle, wherein the end 14b-e1 of “S” portion 14b intersects the middle part 14a-m of “S” portion 14a. In this example, side walls 12a-12d are each about 50-100 μm long. Each of “S” portions 14a and 14b are about 4 μm wide, except for the middle part of “S” portion 14a, which is about twice as wide when one includes the attached end 14b-e1 of “S” portion 14b. It should also be noticed that combination of middle part 14a-m and 14b-e1 provides a broad area with a fairly long flat edge that faces power terminal 24. This reduces the current density between 14a-m and power terminal 24, which reduces the chance of their welding, when they make contact.

The upper surface of movable actuator 14 is substantially flat and coplanar with the upper surface 10a of wafer 10. In this example, movable actuator 14 is thinner than recess 12 is deep. If actuator 14 is 4 μm wide, and recess 12 is about 3 μm deep, actuator 14 could be about 2 μm thick, and spaced about 1 μm above recess bottom wall 12e. Actuator 14 is supported at the upper edges of recess 12 so that actuator 14 is spaced above recess bottom wall 12e. The bottom wall 12e of recess 12 is coated with an insulator (not shown), as for example thermal oxide. Actuator 14 would not normally contact recess bottom wall 12e. However, if it did, there would be no electrical short because of the thermal oxide insulation. Recess side walls 12a-12d are similarly oxide coated but not the edge of power terminal 24 that faces “S” portion 14a.

The electrostatic attraction forces of this microswitch act on ends of “S” portion 14a. The electrostatic attraction forces are produced by two pair of electrostatic electrodes. The first pair of electrostatic electrodes 16 and 18 are disposed at one end 14a-e1 of “S” portion 14a. The second pair of electrostatic electrodes 20 and 22 are disposed at the other end 14a-e2 of “S” portion 14. It can be seen that electrostatic electrode 16 is connected to end 14a-e1, preferably made integrally with actuator “S” portion 14. Electrode 16 is therefore in low resistance electrical communication with end 14a-e1. As formed, electrostatic electrode 18 is adjacent to and closely spaced (about 1-2 μm) from its respective end 14a-e1 of “S” portion 14a. However, after the “S” shaped portion 14a is electrostatically actuated, stiction will cause the ends of 14a to adhere to both electrode 18 and 22. This is key to the operation of this device at low voltages. Once the ends of 14a respectively adhere to electrodes 18 and 22, the spacing between the ends and the electrodes reduces to only about twice the oxide thickness, or about 2000 angstroms (about 0.2 μm). If the spacing during operation was 1-2 μm, the required voltage for actuation would be much larger than 10 volts. An actuation voltage of about 10 volts or less is preferred.

It is convenient to make electrodes 16 and 18 as extensions of material from wafer 10 into recess 12 from recess side wall 12a. Electrode 16 and 18 are thus integral with wafer 10. Electrodes 16 and 18 preferably are the same thickness as actuator 14 and extend from the top of recess 12 to about 1 μm above recess floor 12e. Electrode 18 has a small bump 18a, projection, or other type of conformation on its surface where it will first contact “S” portion 14a. The conformation 18a prevents stiction between electrode 18 and “S” portion 14a during fabrication. Electrode 18 and its conformation 18a are coated with an insulator, as for example thermal oxide, to electrically insulate electrode 18 from “S” portion 14a. The facing edge of “S” portion 14a will also be coated with thermal oxide.

The second pair of electrostatic electrodes 20 and 22 are disposed at the opposite end 14a-e2 of “S” portion 14a. They are similar to what has already been described for electrodes 16 and 18. It can be seen that electrode 20 is connected to end 14a-e2, preferably made integrally. Electrostatic electrode 22 is adjacent and closely spaced to “S” portion 14a, about 1-2 μm as formed. Electrodes 20 and 22 can be extensions of material from wafer 10 into recess 12 from recess side wall 12c. Electrode 20 is thus integral with “S” portion 14a. Electrode 22 is not. Electrodes 20 and 22 preferably are of the same thickness as actuator 14 and extend from the top of recess 12 to about 1 μm above recess floor 12e. Electrode 22 has a small bump 22a, projection, or other type of conformation on its surface where it will first contact “S” portion 14a. The conformation 22a prevents stiction between electrode 22 and “S” portion 14a during fabrication. Electrode 22 and its conformation 22a are coated with an insulator, as for example thermal oxide, to electrically insulate electrode 22 from “S” portion 14a. The facing edge of “S” portion 14a will also be coated with thermal oxide.

An extension of wafer material from side wall 12b into recess 12 forms a power terminal 24. As formed, power terminal 24 is closely spaced (about 4 μm) from the facing edge of the middle part 14a-m of “S” portion 14. Like the electrostatic electrodes 16, 18, 20 and 22, power terminal 24 has the same thickness as actuator 14. Like electrostatic electrodes 16-22, terminal 24 extends down from the top of recess 12 to about 1 μm above recess bottom wall 12e. It is doped to P-type conductivity. If wafer 10 is n-type, this doping would electrically isolate it from the balance of wafer 10. If wafer 10 is intrinsic, terminal 24 is inherently isolated from the balance of wafer 10. It should also be noted that if wafer 10 is p-type, terminal 24 could be placed in an n-well to electrically isolate it. Electrodes 16-22 could be analogously isolated, depending on what type of wafer is used. Terminal 24 also has a conductive coating on its upper surface, which coating extends down side walls of terminal 24, or at least the side wall facing “S” middle part 14a-m.

An end 14b-e1 on the second “S” portion 14b connects with the middle part 14a-m of the first “S” portion 14a and is integral therewith. The lengths of the two “S” portions 14a and 14b are oriented generally perpendicular to one another. I refer to this perpendicular orientation as orthogonal. The other end 14b-e2 of “S” portion 14b is connected to a second power terminal 26. Power terminal 26 has the same thickness as actuator 14, electrostatic electrodes 16-22, and power terminal 24. Like them, power terminal 26 extends down from the top of recess 12 to about 1 μm above recess bottom wall 12e. It is doped to p-type conductivity. If wafer 10 is n-type, this doping would electrically isolate it from the balance of wafer 10. If wafer 10 is intrinsic, power terminal 26 is inherently isolated from the balance of wafer 10. It should also be noted that if wafer 10 is p-type, terminal 26 could be placed in an n-well to electrically isolate it. Power terminal 26 is integrally connected to end 14b-e2 of “S” portion 14b. Repeating, ends 14a-e1, 14a-e2, and 14b-e2 are thus connected to their respective electrodes 16 and 20 and power terminal 26 near the top of the recess, so that “S” portions 14a and 14b are spaced up about 1 μm from recess bottom wall 12e.

Like power terminal 24, power terminal 26 is doped to p-type conductivity. The entirety of “S” portion 14b and the middle part 14a-m of “S” portion 14a are also doped to p-type conductivity. The p-type doping is to a level of about 10¹⁷ cm⁻³. A higher doping can be used if desired. This provides a low resistance electrical path from power terminal 26 to the middle part 14a-m of “S” portion 14a. It can be seen that the doping of middle part 14a-m to p-type conductivity forms a pn junction between middle part 14a-m and the end parts 14a-e1 and 14a-e2 of “S” portion 14a. The end parts of “S” portion 14a are lightly doped to n-type conductivity (about 10¹⁵ cm⁻³) if starting wafer 10 is intrinsic, lightly doped n-type or lightly doped p-type. This electrically isolates middle part 14a-m from each of ends 14a-e1 and 14a-e2 with a low capacitance pn junction, as will hereinafter be explained. This concurrently electrically isolates electrostatic electrodes 16 and 20 from the power terminal 26. Analogously, the pn junctions isolate electrodes 16 and 20 from power terminal 24 when the switch is closed.

Power terminal 26 can be plated with a metal, preferably gold, as well as the top surface of “S” portion 14b and middle part 14a-m. The metal coating would preferably extend down the side edge of middle part 14a-m that faces power terminal 24, to lower its contact resistance with power terminal 24.

Electrodes 16, 18, 20 and 22 are also preferably coated with metal on their upper surfaces. They might be coated with gold or aluminum, and are preferably doped more highly n-type (e.g., about 10¹⁶ cm⁻³ to 10¹⁷ cm⁻³) to lower their electrical resistance. If wafer 10 is of intrinsic material, even a small physical separation between electrodes 16 and 18, and between electrodes 20 and 22 may be adequate to provide enough resistance to electrically isolate them from one another on wafer 10. If not, reversed biased pn junctions (not shown) can be used to electrically isolate them, as previously indicated.

If wafer 10 contains other circuitry, such as integrated circuitry, the metal coatings on electrodes 16, 18, 20, and 21 might be extensions from the metallization pattern of the other circuitry. Analogously, extensions of the metallization pattern from the other circuitry might overlap onto the gold coating of power terminals 24 and 26, and in some instances might even replace the gold coating. As indicated, the edges of electrodes 18 and 22 that face “S” portion 14a are covered with an insulator, such as thermally formed oxide, which is herein more simply referred to as thermal oxide.

If other circuitry is included in wafer 10, as indicated above, wafer 10 may be n-type or p-type to start with. If so, one may wish to choose to electrically isolate electrodes 16, 18, 20 and 22 from each other and from the balance of wafer 10 by other means. This can be readily done by surrounding each of those electrodes with a separate pn junction (not shown). Other techniques could be used as well, depending for example on whether the movable actuator is formed from surface layers of the wafer or from a coating deposited on the wafer surface.

In operation, the microswitch of this invention is closed by applying an electrostatic voltage between electrodes 16 and 18. By electrostatic voltage I mean a direct current voltage sufficient to attract “S” portion 14a near end 14a-e1 to electrode 18 or end 14a-e2 to electrode 22. This voltage may vary, as will hereinafter be explained. As end 14a-e1 is attracted to electrode 18, “S” portion 14a also moves rapidly to the right. This motion to the right brings middle part 14a-m into contact with power terminal 24, which closes the switch. Concurrently, flexible “S” portion 14b stretches to accommodate the movement. By closing the switch, I mean that a low electrical resistance path is formed between power terminals 24 and 26. The path extends through the length of “S” portion 14b and the middle part 14a-m of “S” portion 14a. I believe that the potential difference between middle part 14a-m and power terminal 24 also helps close the switch rapidly.

To open the switch, an electrostatic voltage is applied between electrodes 20 and 22. As this voltage is applied, “S” portion 14a will be attracted to electrode 22 near end 14a-e2, When this occurs, middle part 14a-m will move to the left and peel away from power terminal 24. At the same time, flexible “S” portion 14b contracts, like a spring.

The microswitch actuation voltage should not affect the switched signal. When an electrostatic potential is applied to either pair of electrodes 16 and 18 or 20 and 22, a small portion of the applied potential will be capacitively coupled through the respective electrodes 18 or 20 and associated pn junction in “S” portion 14a. It will appear as signal across the microswitch. The magnitude of the feedthrough voltage can be reduced by reducing the switch actuation voltage and by reducing the electrode and pn junction capacitances. If the actuation voltage is reduced the closing time of the switch will increase. Similarly, if the insulation thickness on electrodes 18 and 22 is increased, to reduce capacitance, the closing time of the switch will also increase. Therefore, the feedthrough voltage was reduced by decreasing the pn junction capacitance. The pn junction capacitance was reduced by using lightly doped n-type material for the n-type parts of “S” portion 14a and applying a 20 volt reverse bias across the pn junctions in “S” portion 14a to widen their depletion regions.

It is desired that “S” portion 14a should not permanently adhere to the related face of either electrode 18 or 22 due to surface adhesion forces (stiction). The voltage required for equilibrium peeling can be estimated by equating the electrostatic force of attraction to the required peeling force. The peeling force per unit area is given by the expression:

$$F = \frac{βγ}{1 - sin θ} \qquad ( 1 )$$

where β=1 μm is the width of the conductor,

$$γ = 140 \pm 70 \frac{mJ}{{m}^{2}}$$

is the surface energy of an SiO₂ surface, and θ is the peeling angle. The electrostatic force per unit area generated between the conductor and the electrode 18 is given by the relationship:

$$F = \frac{{( {V}_{move} )}^{2} {ϵ}_{ox}}{2 {t}^{2}} \qquad ( 2 )$$

where Vₘₒᵥₑ is the applied voltage, εₒₓ is the permitivity of the oxide, and t is the separation between the conductor and the beam. For each unit area of conductor, which peels up from electrode 22, an equivalent unit area of conductor collapses against electrode 18. Therefore, equations (1) and (2) can be equated to solve for the required voltage to move the “S” portion 14a towards either electrode 18 or 22. Using θ=45° and t=0.25 μm yields Vₘₒᵥₑ that is equal to or less than about 1V. Stretching of the “S” portions 14a and 14b has been neglected. Higher voltages will be needed to close or open the switch in <10 μsec. This analysis indicates that stiction is not a significant problem.

I prefer that the microswitch should close in about 10 μsec. If the air gap between the middle part 14a-m and power terminal 24 is about 4 μm when the microswitch is fully open, middle part 14a-m will have to move about 4 μm in about 10 μsec (0.04 m sec⁻¹). Propagation speeds for an “S” shaped actuator with an insulator thickness of 0.5 μm are known to be about 2.7 m sec⁻¹ at 125V applied bias and atmospheric pressure. The propagation speed is proportional to the square of the applied bias. Therefore a speed of 0.4 m sec⁻¹ will require an estimated actuation potential greater than about 48 volts. This number is optimistic since it does not reflect that fact that the microswitch actuator is not moving continuously in one direction. To reduce the required actuation voltage to about 10 volts, the insulator thickness was decreased to 0.2-0.25 μm. In addition, one may choose to operate the switch in a vacuum environment to reduce air damping. If so, the vacuum environment can be provided by bonding a glass cover (not shown) over recess 12. The cover would have a recess in its underside to accommodate any upward motion by actuator 14 due to vibration.

To decrease current density and thus prevent welding between middle part 14a-m and power terminal 24, the contact area should be maximized. The middle part 14a-m is made wider, i.e., bossed, and will tend over small distances to move without bending. Thus, a large fraction of the contact area between middle part 14a-m and power terminal 24 will make contact simultaneously when the microswitch is closed.

When the microswitch closes, the voltage drop between middle part 14a-m and power terminal 24 will cause them to cling together tightly. However, after contact when the voltage drop decreases between them any vibrations or oscillatory motion still present in the “S” portion 14a may pull the middle part 14a-m off of power terminal 24. When the switch opens, the spring-like action of the flexible “S” portions 14a and 14b may cause the switch to oscillate around its final position. If these oscillations are large (e.g., 4 μm) middle part 14a-m may repeatedly strike power terminal 24. Since the switch will be operated in a vacuum, air damping will not be present to help decrease undesirable oscillation. Therefore switch bounce may have to be suppressed by widening and/or thickening “S” portions 14a and 14b.

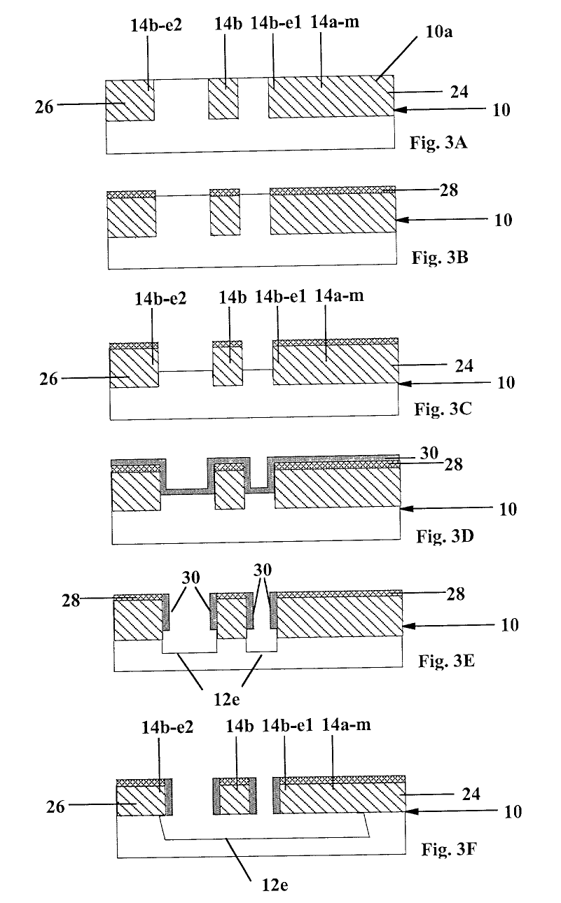

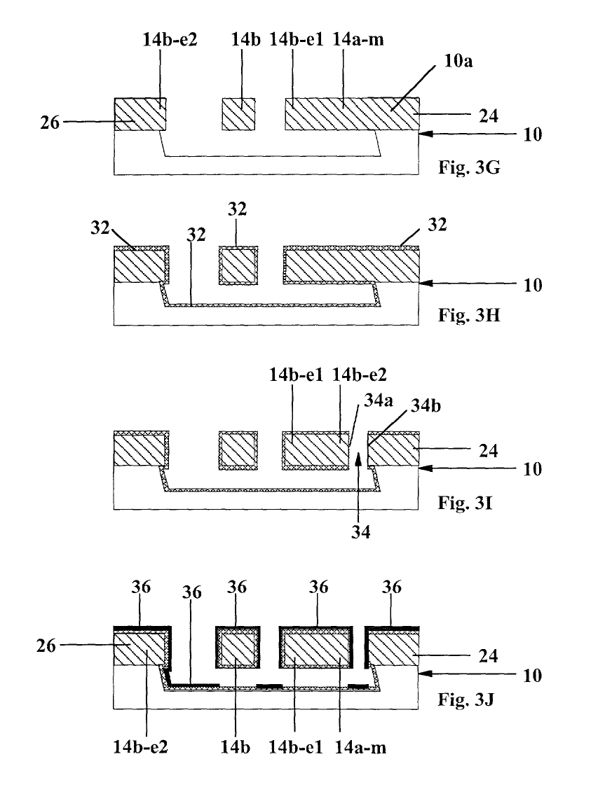

Reference is now also made to FIGS. 3A to 3J, which illustrate the successive steps of one process by which the microswitch of FIGS. 1-2 is made. FIGS. 3A-3J are cross sectional views along the line 3-3 of FIG. 2. FIGS. 3A-3J respectively represent wafer 10 in cross section during the following successive process steps:

A. Dope

B. Oxide deposition for RIE

C. RIE (switch terminal and “S” shaped actuator) still connected, as in FIG. 1

D. Oxide Deposition for recess

E. RIE recess

F. KOH etch (releases first part of structure)

G. Oxide etch

H. Thermal oxidation to form 0.1 μm dry oxide

I. RIE switch terminal release

J. Conformal gold deposition using shallow mask

FIG. 2 is a sketch of the completed microswitch as viewed from the top of the wafer. FIGS. 3A-3J are cross sectional views along the line 3-3 of FIG. 2, respectively showing wafer 10 during process steps A-J.

In step A, the process is begun with a (111) monocrystalline silicon wafer 10 such as previously described. The wafer surface is selectively lightly doped n-type at locations that what will subsequently become the ends of “S” portion 14a, and more heavily n-type at those surface portions that will become electrodes 16, 18, 20 and 22. Wafer 10 is selectively doped more heavily p-type at surface portions that will subsequently become power terminals 24 and 26, “S” portion 14b and the middle of “S” portion 14a. The ends of “S” portion 14a are lightly doped to n-type conductivity to produce a large depletion region at their pn junctions with the middle part of “S” portion 14a. This will act to electrically isolate power terminals 24 and 26 from electrodes 16, 18, 20 and 22.

The electrodes, the power terminals, the entirety of “S” portion 14b and the middle of “S” portion 14a are more heavily doped to increase electrical conductivity and reduce contact resistance.

In step B, one deposits the first masking oxide 28. Depositing rather than growing the masking oxide 28 oxide will probably be needed instead of thermal oxide both because of the large oxide thickness required, and to control the thermal budget. The deposited masking oxide 28 must be thick enough to withstand two vertical reactive ion etch (RIE) steps (C and E) and the KOH etch (F). Deposited masking oxide 28 also eliminates dopant redistribution in the silicon and segregation into the oxide which both occur during a thermal oxidation step.

In step C, the switch structure is defined using a vertical RIE. This step simultaneously defines the integrated dual S-shape of the actuator 14, the electrodes 16-22, and the switch terminals 24 and 26. Portion 14a of the integrated dual S-shaped actuator 14 as defined by this etch is separated from the adjacent parts of electrodes 18 and 22 by a 1-2 μm gap. This gap is needed to grow the thermal insulating oxide. The gap will be eliminated by stiction once the actuator is freed. Notice that pins 18a and 22a, respectively protrude from S-portion 14a into recesses in electrodes 18 and 20. This configuration has been included to prevent stiction from prematurely pinning the actuator portion 14a against electrodes 18 and 22. This etch does not also separate the p-type middle part of actuator portion 14a from power terminal 24. FIG. 1 is a sketch of the microswitch structure at the completion of step C.

In step D, a second masking oxide 30 is deposited and delineated. This oxide 30 is used to protect the structure side walls during KOH etch.

In step E, the silicon wafer is vertically etched by RIE. The RIE etch depth sets the desired spacing between the “S” portions 14a and 14b and recess bottom wall 12e.

In step F, the wafer is etched with KOH. This primarily etches the (111) monocrystalline silicon laterally. The lateral etch is continued until the etch completely undercuts “S” portions 14a and 14b. This releases them from recess bottom wall 12e and provides an inherent spacing therebetween.

In step G, all the oxide is removed by immersion in an appropriate etchant selective to silicon oxide. At this point most “S” portions 14a and 14b are completely shaped and free of recess bottom 12e. However, it is not yet free to move in recess 12 because middle part 14a-m of “S” portion 14a is still connected to power terminal 24. In addition, silicon pins 18a and 22a, still respectively connect electrodes 18 and 22 to “S” portion 14a. As indicated above, these pins act to prevent stiction from pinning the “S” portion 14a against either of electrodes 18 or 22 prematurely. It is to be appreciated that “S” portions 14a and 14b are also connected to their supporting electrodes 16 and 18 and to power terminal 26.

In step H, about 1000A of dry thermal oxide 32 is grown on all exposed surfaces of wafer 10. This oxide will encapsulate the movable actuator of my switch (i.e., “S” portions 14a and 14b) and electrodes 18 and 22, which prevents electrical shorts when the switch is actuated.

In step 1, the switch is masked with photoresist, and the silicon pins 18a and 22a are etched to free them from their respective electrodes. A mating edge section of each of electrodes 18 and 22 facing its respective pin is also removed with this etch. This forms a mating slot in the contact face of the electrode for its respective pin on the facing surface of “S” portion 14a. The slot is large enough such that uninsulated edge surface of the “S” portion 14a, at its respective pin area, will not directly contact its associated electrode 18 or 22. Instead, the uninsulated pin area will nest into the slotted section of the electrode. A 4 um gap 34 between power terminal 24 and the middle part 14a-m of “S” portion 14a is also etched at this time. Delaying the etching of gap 34 until this point leaves the respective facing edges 34a and 34b of middle part 14a-m and power terminal 24 uninsulated. It is to be noted that this etching completes the freeing of flexible actuator 14 in recess 12. It is now only supported by electrodes 16 and 20 and power terminal 26. Flexible actuator 14 is electrically insulated from recess 12 except for its support connections.

In step J, a conformal layer 36 of gold is sputtered through a shadow mask. This must be performed carefully. It is preferred to coat facing edges 34a and 34b in the gap 34 between middle part 14a-m and power terminal 24 but not form a gold bridge between them. This may be accomplished in a variety of ways, including increasing the separation between them before the sputtering. One technique that can be used is to apply an electrostatic voltage between electrodes 20 and 22 before or during sputtering, to open the switch. The switch will tend to stay where it is after the applied voltage is removed. It should also be mentioned that the sputtering mask should prevent gold from bridging over the pn junction areas of “S” portion 14a. Such bridging would provide a low resistance path between the n-type and p-type regions of “S” portion 14a, which is not desired. A shadow mask can be used to define the areas where gold layer 36 will be deposited since fine line patterning is not required.

Stiction is used to establish the preferred contact between the electrodes 16 and 20 and the ends of “S” portion 14a. If proper contact is not achieved during fabrication the switch can simply be actuated to establish the proper contact. By utilizing stiction in this manner the gap distance between each of the electrodes 16 and 20 and the “S” portion 14a is initially set at twice the thermal oxide thickness (0.2 μm).

Silicon pins 18a and 22a are used to prevent stiction from prematurely pinning the “S” portion 14a permanently against either related electrode. Premature pinning would prevent growth of the insulating oxide and short the switch to the respective electrode.

It should also be mentioned that the foregoing examples of this invention describe fabrication of my microswitch in the bulk of a monocrystalline wafer. Alternative fabrication techniques are also possible. For example, wafer 10 could be intrinsic and initially etched to form an appropriately configured recess, that is similar to recess 12 as hereinbefore described. The recess could be filled with oxide and the surface planarized. Then, a blanket polycrystalline silicon coating would be deposited. The polycrystalline silicon layer would then be selectively etched through its thickness to define the configuration see in FIG. 1. After that, the steps would be analogous to what has been hereinbefore described. The oxide filling the recess need not be etched until it is removed entirely, which releases the flexible actuator 14. After that, the polycrystalline layer would be processed essentially as hereinbefore described to separate the pins 18a and 22a from “S” portion 14a and also from power terminal 24. Then, the finishing steps would be analogous to what has hereinbefore described.

The foregoing discussion discloses and describes several exemplary embodiments of the present invention. One skilled in the art will readily recognize from such discussion, and from the accompanying drawings and claims, that various changes, modifications and variations can be made therein without departing from the spirit and scope of the invention as defined in the following claims.

1. A micro electromechanical system relay comprising:
a semiconductor wafer base, said wafer base having opposed major surfaces and a recess in one of said surfaces, said recess having a periphery defined by side walls and a bottom surface;
a semiconductor movable actuator member disposed and movably supported over said recess, said movable actuator member having opposed major surfaces generally parallel to said major surfaces of said wafer and having edge surfaces defining first and second flexible portions of said actuator member, each of said flexible portions having first and second ends, and said first flexible portion including first and second end parts and a middle part therebetween;
said second flexible portion and the middle part of said first flexible portion being of the same electrical conductivity type;
a connection between the first end of said second flexible portion and the middle part of said first flexible portion, whereby said first and second flexible portions of said movable actuator are orthogonally oriented with respect to one another over said recess in a plane parallel to said major wafer surfaces and said second flexible portion is in low resistance electrical communication with the middle part of said first flexible portion;
the second end of said second flexible portion of said movable actuator connected to a first part of said recess side wall;
a first power terminal adjacent said first part of said recess side wall, said first power terminal in low resistance electrical communication with the second end of said second flexible portion, so as to also be in low resistance electrical communication with the middle part of said first flexible portion;
a second power terminal, said second power terminal having a portion disposed adjacent the middle part of said first flexible portion opposite from said second flexible portion, whereby the middle part of said first flexible portion can contact said second power terminal when said first flexible portion flexes, and thereby provide low resistance electrical communication between said first and second power terminals;
pn junctions respectively electrically isolating the middle part of said first flexible portion from its first and second end parts;
the first end of said first flexible portion of said movable actuator connected to a second part of said recess side wall, said second part of said recess side wall being disposed between said first and second power terminals;
a first actuator control terminal adjacent said recess side wall second part, said first actuator terminal being in low electrical resistance communication with the first end of said first flexible portion;
the second end of said first flexible portion of said movable actuator connected to a third part of said recess side wall, said third part of said recess side wall being disposed between said first and second power terminals opposite from said second part of said recess side wall;
a second actuator control terminal adjacent said recess side wall third part, said second actuator terminal being in low resistance communication with the second end of said first flexible portion;
a first electrostatic electrode having at least a portion adjacent the first end of said first flexible portion, the first electrostatic electrode portion being disposed near an edge of said first end that is on a side of said first flexible portion opposite from said second power terminal, said first electrostatic electrode and said first actuator control terminal being separated by an electrical resistance whereby application of an electrical potential between them can electrostatically attract the first flexible portion towards said first electrostatic electrode and move it away from contact with said second power terminal; and
a second electrostatic electrode having at least a portion in said recess adjacent the second end of said first flexible portion, the second electrostatic electrode portion being disposed near an edge of the second end part that is on a side of said first flexible portion towards said second power terminal, said second electrostatic electrode and said first actuator control terminal being separated by an electrical resistance whereby application of an electrical potential between them can electrostatically attract the first flexible portion towards said second electrostatic electrode and move it into contact with said second power terminal, said contact providing low electrical resistance communication between said first and second power terminals.

2. The micro electromechanical system relay of claim 1 in which at least one of the flexible portions of said movable actuator is S-shaped.

3. The micro electromechanical system relay of claim 1 in which both flexible portions of said movable actuator are S-shaped.

4. The micro electromechanical system relay of claim 1 in which:
each flexible portion of said movable actuator is S-shaped;
both flexible portions of said movable actuator are integral parts of said movable actuator;
said movable actuator is integral with the wafer base;
said flexible portions are disposed in a recess in the wafer base; and
said first and second electrostatic electrode portions are orthogonal to the first and second power terminals, so that the application of an electrostatic voltage to either electrostatic electrode moves the first flexible portion of said movable actuator both longitudinally and laterally.

5. The micro electromechanical system relay of claim 4 in which:
said wafer base and said movable actuator are monolithic silicon; and
at least some of said electrodes and terminals are in communication with a metallization pattern on said wafer base.

6. The micro electromechanical system of claim 5 in which at least one of the ends of the first flexible portion of said movable actuator has at least one means for reducing adhesion of that end section to its electrostatic electrode during fabrication before said actuator is completely released from the wafer base from which it was formed.

7. The micro electromechanical system of claim 6 in which the means for reducing adhesion of the actuator to the electrostatic electrode is a surface conformation on the electrostatic electrode facing the movable actuator.

8. The micro electromechanical system of claim 5 in which each of the end parts of the first flexible portion of said movable actuator has at least one projection thereon facing its respective electrostatic electrode, which projection helps reduce adhesion of that end to its electrostatic electrode during fabrication before said actuator is completely released from the wafer base from which it was formed.

9. The micro electromechanical system of claim 8 in which said projection insulatingly nests in a slot in a facing electrostatic electrode.

10. The micro electromechanical system of claim 5 in which at least one of the second power terminal and the middle part of the first flexible portion of said movable actuator have means for reducing contact resistance therebetween.

11. The micro electromechanical system of claim 10 in which the means for reducing contact resistance between them includes at least one of the means selected from the group consisting of highly doped areas and metallized areas.

12. The micro electromechanical system of claim 5 in which the middle part of the first flexible portion of said movable actuator has means thereon for assisting in making contact with said second power terminal during longitudinal and lateral movement of said first flexible portion.

13. The micro electromechanical system of claim 12 in which the means is a broad surface and straight edge on the middle part of the first flexible portion of said movable actuator that contacts a straight edge on said power terminal.
